(19) United States
(12) Patent Application Publication
(10) Pub. No.: US 2020/0320947 A1
(43) Pub. Date: Oct. 8, 2020

(54) GATE DRIVER CIRCUIT BASED ON IGZO MANUFACTURING PROCESS AND LIQUID CRYSTAL DISPLAY PANEL

(71) Applicant: Shenzhen China Star Optoelectronics Semiconductor Display Technology Co., Ltd., Shenzhen, Guangdong (CN)

(72) Inventor: Longqiang SHI, Shenzhen, Guangdong (CN)

(73) Assignee: Shenzhen China Star Optoelectronics Semiconductor Display Technology Co., Ltd., Shenzhen, Guangdong (CN)

(21) Appl. No.: 16/060,521

(22) PCT Filed: Jan. 25, 2018
(86) PCT No.: PCT/CN2018/074101

§ 371 Date: Jun. 8, 2018

(30) Foreign Application Priority Data
Aug. 15, 2017 (CN) 201710698881.2

(51) Int. Cl. G09G 3/36; H01L 27/12

(52) U.S. Cl. CPC G09G 3/3677; H01L 27/1225

(57) ABSTRACT

A gate driver circuit based on IGZO manufacturing process and a liquid crystal display panel are provided. The gate driver circuit includes: N stages of GOA gate driver circuit module connected in cascade. Each of the stages of GOA gate driver circuit module includes a GOA circuit module and an amplification circuit module electrically connected with each other. The GOA circuit module is operable to keep an output level fixed when a first clock signal is in a holding period and is also operable to set a previous-stage gate drive signal as a current-stage gate drive signal to be output. The amplification circuit module is operable to amplify the current-stage gate drive signal and outputs an amplified current-stage gate drive signal through the second output terminal. Output waveforms of a current-stage gate drive signal output from the GOA circuit can be improved.

### CROSS REFERENCE TO RELATED APPLICATIONS

This application is a national stage application of PCT/CN2018/074101 filed on Jan. 25, 2018 and claiming foreign priority of Chinese Patent Application No. 201710698881.2 filed on Aug. 15, 2017.

### BACKGROUND OF THE INVENTION

### 1. Field of the Invention

The present invention relates to the technical field of terminal devices, and more particularly to a gate driver circuit based on IGZO (Indium Gallium Zinc Oxide) manufacturing process and a liquid crystal display panel.

### 2. The Related Arts

GOA (Gate Driver on Array) technology is an array substrate row driving technique, which uses an array manufacturing process of thin-film transistor (TFT) liquid crystal displays to form a gate scan driver circuit on a TFT array substrate for realizing a row-by-row scanning based driving operation, which exhibits the advantages of reduction of fabrication cost and availability of a slim frame design of a panel and has been applied to various display device. The GOA circuit features two basic functions, which are: output of a gate scan drive signal to drive a gate line of a panel for turning on a TFT located in a display zone to achieve charging of a pixel; and functionality of shift register, wherein after a gate scan drive signal has been output, through the control achieved with a clock signal, output of a next gate scan drive signal is made and this operation is past down in sequence.

IGZO (Indium Gallium Zinc Oxide) is a non-crystalline oxide containing indium, gallium, and zinc, possessing advantages including relatively high mobility and device stability, making it favorable for upgrading row scan rate of pixels. Thus, the GOA circuits are commonly integrated using an IGZO manufacturing process.

Few studies of IGZO based GOA circuits are available in the state of the art. Particularly, for large-sized GOA circuits, issues related to the IGZO material itself must be overcome. With the trend of development of large-sized liquid crystal display panels, the size of the panel and the number of gate drive rows will be definitely increased, and the loading of GOA would also be increased. This increases power consumption of the GOA circuit.

### SUMMARY OF THE INVENTION

The technical issue that the present invention is made to address is to provide a gate driver circuit based on an IGZO manufacturing process and a liquid crystal display panel, which help improve an output waveform of a current stage gate drive signal supplied from a GOA circuit, reduce rising edge time and failing edge time, and also reduce circuit power consumption.

In an aspect, an embodiment of the present invention discloses a gate driver circuit based on GIZO manufacturing process, which comprises: N stages of gate-driver-on-array (GOA) gate driver circuit module connected in cascade, wherein each of the stages of GOA gate driver circuit module comprises a GOA circuit module and an amplification circuit module electrically connected with each other;

the GOA circuit module comprises a first input terminal, a second input terminal, and a first output terminal, the first input terminal and the second input terminal respectively receiving a previous-stage gate drive signal and a first clock signal; the GOA circuit module is operable to keep an output level of the first output terminal fixed when the first clock signal is in a holding period and is also operable to set the previous-stage gate drive signal as a current-stage gate drive signal to be output through the first output terminal when the first clock signal is in a turn-on period; and

the amplification circuit module comprises a third input terminal and a second output terminal, the third input terminal receiving the current-stage gate drive signal, the amplification circuit module amplifying the current-stage gate drive signal and outputting an amplified current-stage gate drive signal through the second output terminal.

Optionally, the amplification circuit module comprises a first thin-film transistor (TFT), a second TFT, a third TFT, a the fourth TFT; a source electrode the first TFT is electrically connected with a drain electrode of the second TFT and a gate electrode of the fourth TFT; a gate electrode of the second TFT is electrically connected with the first output terminal of the GOA circuit module and a gate electrode of the third TFT; and a source electrode of the third TFT is electrically connected with a drain electrode of the fourth TFT; and a gate electrode of the first TFT, a drain electrode of the first TFT, and a drain electrode of the third TFT are electrically connected with a first voltage source (VGH); and a source electrode of the second TFT and a source electrode of the fourth TFT are electrically connected with a second voltage source (VSS).

Optionally, the amplification circuit module further comprises a first capacitor, the first capacitor being connected between the gate electrode and the source electrode of the third TFT.

Optionally, the GOA circuit module comprises a pull-down holding circuit unit, a second capacitor, a fifth TFT, and a sixth TFT, the pull-down holding circuit unit comprising a first terminal, a second terminal, a third terminal, and a fourth terminal; a source electrode of the fifth TFT is electrically connected with the first terminal and a gate electrode of the sixth TFT, a source electrode of the sixth TFT being electrically connected with the third terminal, the first output terminal, and the second voltage source (VSS), a gate electrode and a drain electrode of the fifth TFT being electrically connected with the first input terminal; a drain electrode of the sixth TFT and the fourth terminal are electrically connected with the second input terminal, the second terminal being electrically connected with the second voltage source (VSS); and the second capacitor is connected between the gate electrode and the source electrode of the sixth TFT.

Optionally, the GOA circuit module further comprises: a seventh TFT and an eighth TFT; a drain electrode of the seventh TFT is electrically connected with the source electrode of the fifth TFT and the gate electrode of the sixth TFT, a gate electrode of the seventh TFT being electrically connected with a gate electrode of the eighth TFT, a drain electrode of the eighth TFT being electrically connected with the source electrode of the sixth TFT; and a source electrode of the seventh TFT and a drain electrode of the eighth TFT are electrically connected with the second voltage source (VSS).

In another aspect, an embodiment of the present invention discloses a liquid crystal display panel. The liquid crystal display panel comprises a gate driver circuit based on IGZO manufacturing process as described above.

Embodiments of the present invention provide a gate driver circuit based on IGZO manufacturing process and a liquid crystal display panel, wherein the gate driver circuit comprises: N stages of GOA gate driver circuit module connected in cascade. Each of the stages of GOA gate driver circuit module comprises a GOA circuit module and an amplification circuit module electrically connected with each other. The GOA circuit module is operable to keep an output level fixed when a first clock signal is in a holding period and is also operable to set a previous-stage gate drive signal as a current-stage gate drive signal to be output. The amplification circuit module is operable to amplify the current-stage gate drive signal and outputs an amplified current-stage gate drive signal through the second output terminal. This helps improve output waveforms of a current-stage gate drive signal output from the GOA circuit, reduces rising edge time and falling edge time, and also reduces circuit power consumption.

### BRIEF DESCRIPTION OF THE DRAWINGS

To more clearly explain the technical solution proposed in embodiments of the present invention and that of the prior art, a brief description of the drawings that are necessary for describing the embodiments or the prior art is given as follows. It is obvious that the drawings that will be described below show only some embodiments of this application. For those having ordinary skills of the art, other drawings may be readily available from these attached drawings without the expense of creative effort and endeavor.

FIG. 1 is a schematic view illustrating a connection arrangement of a GOA circuit module provided in an embodiment of the present invention;

FIG. 2 is a schematic view illustrating waveforms obtained with the GOA circuit module provided in an embodiment of the present invention;

FIG. 3 is a schematic view illustrating a gate driver circuit based on IGZO manufacturing process according to an embodiment of the present invention;

FIGS. 4A and 4B are schematic views illustrating connection arrangements of two amplification circuit modules provided in embodiments of the present invention;

FIG. 5 is a schematic view illustrating waveforms of a gate driver circuit provided in an embodiment of the present invention; and

FIGS. 6A and 6B are schematic views illustrating gate driver circuits based on an IGZO manufacturing process according to another embodiment of the present invention.

### DETAILED DESCRIPTION OF THE PREFERRED EMBODIMENTS

To provide better understanding of the solutions of the present invention for those skilled in the art, a clear and complete description will be given to the technical solutions provided by embodiments of the present invention with reference to the attached drawings of the embodiments of the present invention. However, the embodiments so described are only some, but not all, of the embodiments of the present invention. Based on the embodiment of the present invention, other embodiments are available to those having ordinary skills of the art without the expense of creative effort and endeavor and are considered belonging to the scope of protection of the present invention.

Terms, such as “first”, “second”, and “third”, as used in the disclosure, the claims, and the above-described drawings of the present invention, are provided for distinguishing of different objects and are not provided for identifying specific sequences thereof. In addition, terms, such as “comprising” and any variations thereof, are used to intentionally cover inclusion in the sense of being not exclusive. For example, a process, a method, a system, a product, or installation that comprises a series of steps or units is not limited to the steps or units so listed and could optionally include steps or units that have not been listed, or could optionally further include other inherent steps or units of such a process, method, product or installation.

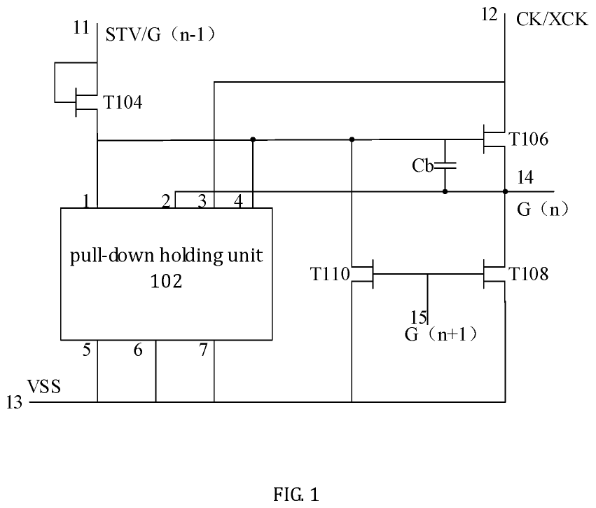

Referring to FIG. 1, which is a schematic view illustrating a connection arrangement of a gate-driver-on-array (GOA) circuit module provided in an embodiment of the present invention, the GOA circuit module 100 comprises: four terminals, which are shown as terminal 11 to terminal 14 in the drawings, wherein terminal 11 and terminal 13 are respectively a first output terminal 11, a second input terminal 12, and an input terminal 13, and terminal 14 is a first output terminal 14. The first input terminal 11 is provided for input of a previous-stage gate drive signal G (n−1). The second input terminal 12 receives input of a first clock signal CK/XCK. The input terminal 13 is provided for input of a first direct current (DC) signal VSS and may also be electrically connected with the first voltage source VSS.

The GOA circuit module 100 may comprise a pull-down holding unit 102, two thin-film transistors (TFTs), which are shown as T104 and T106 in the drawings, and a bootstrap capacitor, which is shown as Cb in the drawings. The pull-down holding unit 102 comprises seven terminals, which are shown as terminal 1 to terminal 7 in the drawings. A gate electrode and a drain electrode of T104 are both electrically connected with the first input terminal 11; a source electrode of T104 is electrically connected with terminal 1, the terminal 4, and a gate electrode of T106; a drain electrode of T106 and the terminal 3 are electrically connected with the second input terminal 12. Terminal 2 is electrically connected with a source electrode of T106. The bootstrap capacitor Cb is connected between the gate electrode and the source electrode of T106. The source electrode of T106 is electrically connected with the first output terminal 14 and the input terminal 13.

In an embodiment of the present invention, the GOA circuit module 100 may further comprise another two TFTs, which are shown as T108 and T110 in the drawings. A drain electrode of T108 is electrically connected with the source electrode of T106; a source electrode of T108 is electrically connected with the input terminal 13. A gate electrode of T110 is electrically connected with a gate electrode of T108; a drain electrode of T110 is electrically connected with the gate electrode of T106 and the source electrode of T104; a source electrode of T110 is electrically connected with the input terminal 13. Terminal 5, terminal 6, and terminal 7 of the pull-down holding unit are electrically connected with the input terminal 13.

In another embodiment of the present invention, the GOA circuit module 100 further comprises another input terminal 15. The input terminal 15 is provided for input of a next-stage gate drive signal. The input terminal 15 is electrically connected with the gate electrode of T110 and the gate electrode of T108.

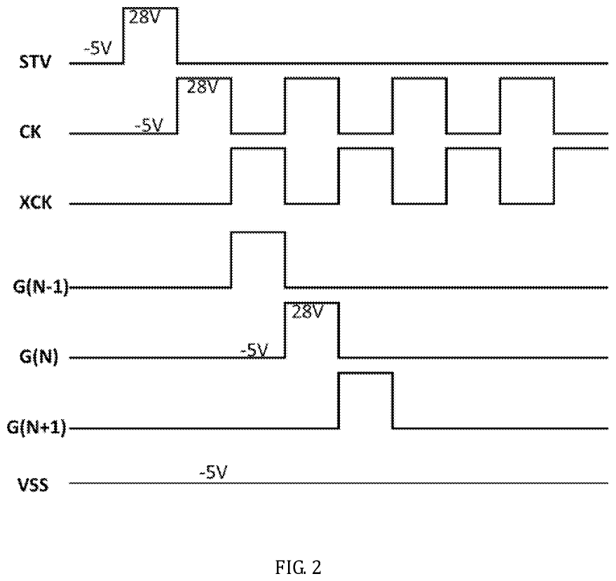

The principle of operation of the GOA circuit module 100 is as follows. When input of G(n) is a high level signal, charging is made to the bootstrap capacitor Cb and the pull-down holding unit functions to maintain a closed condition to input of a previous-stage gate signal and the first clock signal, namely holding output of low-voltage DC signal (the first CD signal). When input of G(n) is a low level signal, the bootstrap capacitor Cb discharges so that output is made through the first output terminal 14 to provide a current-stage gate drive signal G(n). Optionally, the first DC signal VSS can be a low-voltage DC signal of −5V, namely the potential is −5V. FIG. 2 is a schematic view illustrating some waveforms involved in the operation of the GOA circuit module provided in the embodiment of the present invention, in which STV is a starting signal, namely a first-stage get drive signal; and CK/XCK are high-frequency alternate current (AC) signals that are exactly opposite to each other, of which high and low potential levels are respectively 28V and −5V.

In some embodiments, the first clock signals that are input through the third input terminals 13 of two adjacent stages of GOA circuit module are exactly opposite high-frequency AC signals, wherein if the previous-stage GOA circuit module is supplied with a first clock signal that is CK, then the current-stage GOA circuit module is supplied with a first clock signal that can be XCK.

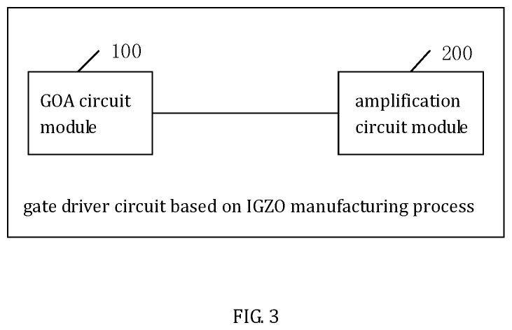

Referring to FIG. 3, which is a schematic view illustrating a gate driver circuit based on IGZO manufacturing process according to an embodiment of the present invention, the gate driver circuit 10 comprises: N stages of GOA gate driver circuit module connected in cascade, wherein each stage of GOA gate driver circuit module comprises a GOA circuit module 100 and an amplification circuit module 200 electrically connected with each other.

The GOA circuit module 100 comprises the first input terminal 11, the second input terminal 12 and the first output terminal 14. The first input terminal 11 and the second input terminal 12 respectively receive inputs of a previous-stage gate drive signal G(n−1) and a first clock signal CK/XCK. The GOA circuit module 1000 is operable to keep an output level of the first output terminal 14 fixed when the first clock signal CK/XCK is in a holding period and is also operable to set the previous-stage gate drive signal G (n−1) as a current-stage gate drive signal G (n) to be output through the first output terminal 14 when the first clock signal CK/XCK is in a turn-on period.

The amplification circuit module 200 comprises a third input terminal 16 and a second output terminal 19. The third input terminal 4 is provided for input of the current-stage gate drive signal G (n). The amplification circuit module 200 carries out an operation of amplifying the current-stage gate drive signal G(n) and outputs an amplified current-stage gate drive signal G(n)_out through the second output terminal 19.

Through practice of the embodiment of the present invention, output waveforms of the current-stage gate drive signal output from the GOA circuit module can be improved; rising edge time and falling edge time can be reduced; and circuit power consumption can also be reduced.

It is noted that the GOA circuit module 100 involved in the embodiment of the present invention can be specifically referred to the schematic view of the connection arrangement of the GOA circuit module 100 shown in FIG. 1 and repeated description will be omitted.

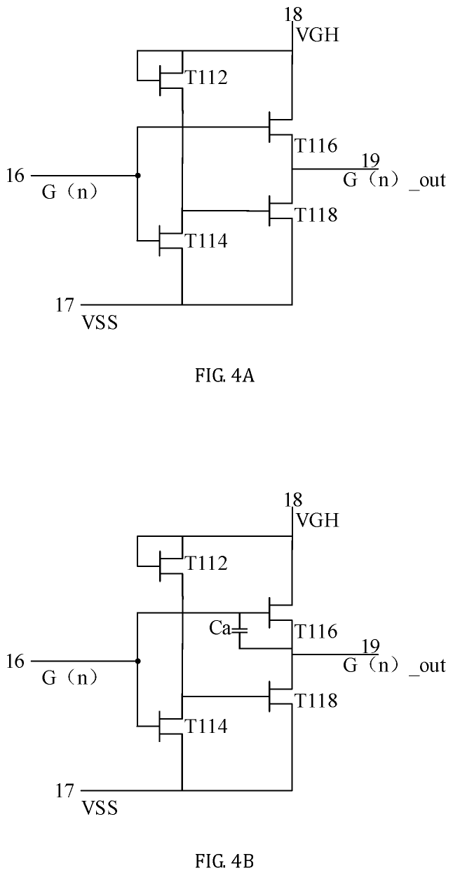

Referring to FIG. 4A, which is a schematic view illustrating a connection arrangement of the amplification circuit module 200 provided in an embodiment of the present invention, the amplification circuit module 200 comprises a third input terminal 16, a fourth input terminal 17, a fifth input terminal 18, and a second output terminal 19, wherein the third input terminal 16 receives an input of a current-stage gate drive signal G (n). The fourth input terminal 17 receives an input of a first CD signal VSS and may also be electrically connected with a first voltage source VSS, where the first voltage source could be a low-voltage DC potential source of −5V. The fifth input terminal 18 receives an input of a second DC signal VGH and may also be electrically connected with a second voltage source VGH, where the second voltage source could be a high-voltage DC potential source of 28V.

The amplification circuit module 200 may comprise fourth thin-film transistors, which are shown as a first thin-film transistor T112, a second thin-film transistor T114, a third thin-film transistor T116, and a fourth thin-film transistor T118 in the drawings. A gate electrode and a drain electrode of the first TFT (T112) re electrically connected with the fifth input terminal 18. A source electrode of T112 is electrically connected with a drain electrode of the second TFT (T114) and a gate electrode of the fourth TFT (T118). A gate electrode of the second TFT (T114) and a gate electrode of the third TFT (T116) are electrically connected with the third input terminal 16. A drain electrode of the third TFT (T116) is electrically connected with the fifth input terminal 18. A source electrode of the third TFT (T116) and a drain electrode of the fourth TFT (T118) are electrically connected with the second output terminal 19. A source electrode of the second TFT (T114) and a drain electrode of the fourth TFT (T118) are electrically connected with the fourth input terminal 17.

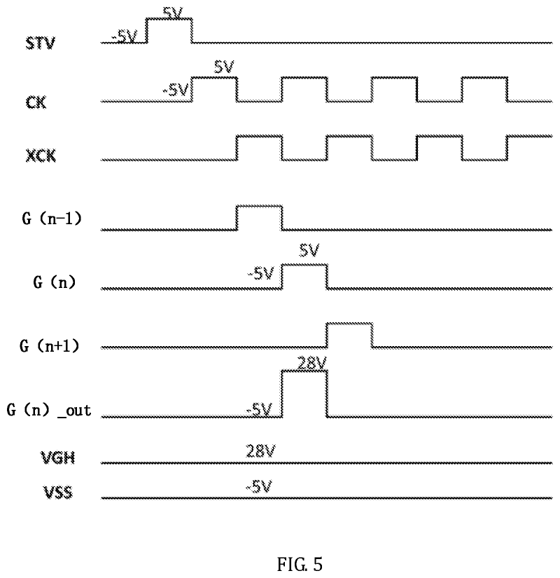

The principle of operation of the amplification circuit module 200 is as follows. When G(N) is of a low level of −5V, the second TFT (T114) and the third TFT (T116) are in a cut-off/turn-off condition. Since the gate electrode of the first TFT (T112) is connected to VGH (28V), the first TFT (T112) is turned on. The level of S(N) is 28V and the fourth TFT (T118) is conducting and G(n)_out outputs the low level −5 of VSS. When G(N) is of a high level of 5V, the second TFT (T114) and the third TFT (T116) are conducting. Since the gate electrode of the first TFT (T112) is connected to VGH (28V), the first TFT (T112) and the third TFT (T116) are conducting. Due to voltage division of T112 and T114, the level of S(N) is −5V, so that the fourth TFT (T118) is in a turn-off condition; G(n)_out outputs the high level 28V of VGH. Specific reference may be made to FIG. 5, some waveforms related to the gate driver circuit of the embodiment of the present invention as shown.

In some feasible embodiments, referring to the illustration of FIG. 4B, a schematic view illustrating a connection arrangement of another amplification circuit module 200 provided in an embodiment of the present invention is provided. The amplification circuit module 200 may further comprise a capacitor, which is shown as a bootstrap capacitor Ca in the drawings, wherein Ca is connected between the gate electrode and the source electrode of the third TFT (T116).

The principle of operation of the amplification circuit module 200 is as follows. When G(N) is of a low level of −5V, T114 and T116 are in a turn-off condition. Since the gate electrode of T112 is connected to VGH (28V), the first TFT (T112) is conducting. The level of S(N) is 28V and the fourth TFT (T118) is conducting and G(n)_out outputs the low level −5 of VSS. When G(N) is of a high level of 5V, T114 and T116 are conducting. Since the gate electrode of T112 is connected to VGH (28V), T112 and T116 are conducting. Due to voltage division of T112 and T114, the level of S(N) is −5V, so that T118 is in a turn-off condition; G (N)_out outputs the high level 28V of VGH. Further, during the process that the potential of G(n)_out changes from the original −5V to 28V, due to capacitance of Ca, the level of T(N) is raised even higher from 28V. Thus, the third TFT (T116) could be conducting better and the high level of VGH could be transmitted, faster and better, to G(n)_out, so that the circuit may have better gate output waveform and the circuit is more stable. Specific reference may be made to FIG. 5, some waveforms related to the gate driver circuit of the embodiment of the present invention as shown.

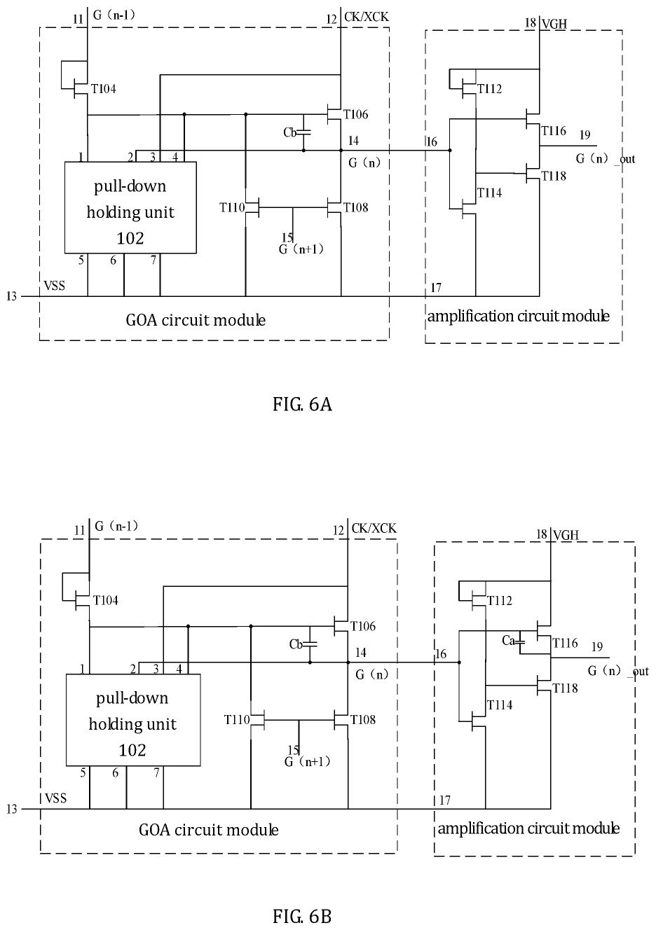

Referring to FIGS. 6A and 6B, schematic views illustrating gate driver circuits based on an IGZO manufacturing process according to another embodiment of the present invention are provided, wherein specifics of the GOA circuit module 100 and the amplification circuit module 200 could be referred to the descriptions given in the above-described, related embodiments and repeated description will be omitted here.

An embodiment of the present invention also provides a liquid crystal display panel. The liquid crystal display panel may comprise the gate driver circuit based on IGZO manufacturing process schematically illustrated in FIG. 6A or 6B. Specifics may be referred to the descriptions given in the above-described, related embodiments and repeated description will be omitted here.

It is noted that for simplification of description, the examples of the method that are provided above are described as a combination of a series of operations. However, those skilled in the art may appreciate that the present invention is not limited to the sequence of the operation so described, because according to the present invention, some of the steps may be conducted in other sequences or conducted simultaneously. Further, those skilled in the art may also appreciate that the examples described in the disclosure are considered preferred embodiments and operations and modules involved may not be necessary to this invention.

In the above examples, the descriptions provided for each of the examples are such that specific highlighting is made for each individual example. Certain non-described parts of one embodiment may be referred to a corresponding description given in other embodiments.

It is appreciated that in the embodiments provided in this application, a devices disclosed therein could also be realized with other ways. For example, the device embodiments described above are only illustrative. For example, division of units so provide is just one logic functional way of division and other ways of division may be adopted in reduction into practice. For example, multiple units or assemblies may be combined together or may be integrated with another system, or some features may be omitted or not executed. In addition, mutual coupling or direct coupling or communicative connection as displayed or discussed could be made through some ports, and indirect coupling or communicative connection between devices or units could be electric or other forms.

Units that are described as separate parts may be or may not be physically separated. Components for unit display may be or may not be a physical unit, namely being possibly located at one site or being distributed in multiple network units. It is possible to make selection of a portion or all of the units according to practical needs in order to achieve the purposes of the solution of the embodiment.

In addition, each functional unit of each example of the present invention can be integrated in one processing unit or it is possible for each of the units to be physically independently present, or it is also possible for two or more than two units to be integrated in one unit. The integrated unit could be realized in the form of hardware or could be realized in the form of functional unit of software.

The integrated unit, if realized in the form of functional unit of software and sold or used as an independent product, could be stored in computer readable storage medium. Based on such understanding, the technical solution of the present invention, or speaking in a different way, the part that makes contribution to the state of the art, or all or part of the technical solution, could, in the nature thereof, be presented in the form of software product and such a compute software product is stored in a storage medium, including certain instructions that allow computer facility (which could be a person computer, a server, or a network device) to carry out all or some of the steps of the methods described in each embodiment of the present invention. Such storage medium could be all sorts of medium that is capable of storing program codes, including: USB disk, read-only memory (ROM), random access memory (RAM), portable disk, magnetic disk, or optic disk.

In the description given above, the embodiments are provided for illustrating, but not limiting, the technical solution of the present invention. Although the above-described embodiments provide a detailed explanation to the present invention, those skilled in the art would appreciate that modifications could be made on the technical solution described in each of the above-described embodiments, or equivalent substitutes could be made for some technical features of these embodiments. Such modifications and equivalents do not make the nature of the corresponding technical solution departing from the scope of the technical solution of each of these embodiments of the present invention.

What is claimed is:

1. A gate driver circuit based on indium-gallium-zinc-oxide (IGZO) manufacturing process, comprising: N stages of gate-driver-on-array (GOA) gate driver circuit module connected in cascade, wherein each of the stages of GOA gate driver circuit module comprises a GOA circuit module and an amplification circuit module electrically connected with each other;
the GOA circuit module comprises a first input terminal, a second input terminal, and a first output terminal, the first input terminal and the second input terminal respectively receiving a previous-stage gate drive signal and a first clock signal; the GOA circuit module is operable to keep an output level of the first output terminal fixed when the first clock signal is in a holding period and is also operable to set the previous-stage gate drive signal as a current-stage gate drive signal to be output through the first output terminal when the first clock signal is in a turn-on period; and
the amplification circuit module comprises a third input terminal and a second output terminal, the third input terminal receiving the current-stage gate drive signal, the amplification circuit module amplifying the current-stage gate drive signal and outputting an amplified current-stage gate drive signal through the second output terminal.

2. The gate driver circuit according to claim 1, wherein the amplification circuit module comprises a first thin-film transistor (TFT), a second TFT, a third TFT, a the fourth TFT;
a source electrode of the first TFT is electrically connected with a drain electrode of the second TFT and a gate electrode of the fourth TFT; a gate electrode of the second TFT is electrically connected with the first output terminal of the GOA circuit module and a gate electrode of the third TFT; and a source electrode of the third TFT is electrically connected with a drain electrode of the fourth TFT; and
a gate electrode of the first TFT, a drain electrode of the first TFT, and a drain electrode of the third TFT are electrically connected with a first voltage source (VGH); and a source electrode of the second TFT and a source electrode of the fourth TFT are electrically connected with a second voltage source (VSS).

3. The gate driver circuit according to claim 2, wherein the amplification circuit module further comprises a first capacitor, the first capacitor being connected between the gate electrode and the source electrode of the third TFT.

4. The gate driver circuit according to claim 2, wherein the GOA circuit module comprises a pull-down holding circuit unit, a second capacitor, a fifth TFT, and a sixth TFT, the pull-down holding circuit unit comprising a first terminal, a second terminal, a third terminal, and a fourth terminal;
a source electrode of the fifth TFT is electrically connected with the first terminal and a gate electrode of the sixth TFT, a source electrode of the sixth TFT being electrically connected with the third terminal, the first output terminal, and the second voltage source (VSS), a gate electrode and a drain electrode of the fifth TFT being electrically connected with the first input terminal; a drain electrode of the sixth TFT and the fourth terminal are electrically connected with the second input terminal, the second terminal being electrically connected with the second voltage source (VSS); and the second capacitor is connected between the gate electrode and the source electrode of the sixth TFT.

5. The gate driver circuit according to claim 4, wherein the GOA circuit module further comprises: a seventh TFT and an eighth TFT;
a drain electrode of the seventh TFT is electrically connected with the source electrode of the fifth TFT and the gate electrode of the sixth TFT, a gate electrode of the seventh TFT being electrically connected with a gate electrode of the eighth TFT, a drain electrode of the eighth TFT being electrically connected with the source electrode of the sixth TFT; and a source electrode of the seventh TFT and a drain electrode of the eighth TFT are electrically connected with the second voltage source (VSS).

6. A liquid crystal display panel, comprising a gate driver circuit based on indium-gallium-zinc-oxide (IGZO) manufacturing process, wherein the gate driver circuit comprises N stages of gate-driver-on-array (GOA) gate driver circuit module connected in cascade, wherein each of the stages of GOA gate driver circuit module comprises a GOA circuit module and an amplification circuit module electrically connected with each other;
the GOA circuit module comprises a first input terminal, a second input terminal, and a first output terminal, the first input terminal and the second input terminal respectively receiving a previous-stage gate drive signal and a first clock signal; the GOA circuit module is operable to keep an output level of the first output terminal fixed when the first clock signal is in a holding period and is also operable to set the previous-stage gate drive signal as a current-stage gate drive signal to be output through the first output terminal when the first clock signal is in a turn-on period; and
the amplification circuit module comprises a third input terminal and a second output terminal, the third input terminal receiving the current-stage gate drive signal, the amplification circuit module amplifying the current-stage gate drive signal and outputting an amplified current-stage gate drive signal through the second output terminal.

7. The liquid crystal display panel according to claim 6, wherein the amplification circuit module comprises a first thin-film transistor (TFT), a second TFT, a third TFT, a the fourth TFT;
a source electrode of the first TFT is electrically connected with a drain electrode of the second TFT and a gate electrode of the fourth TFT; a gate electrode of the second TFT is electrically connected with the first output terminal of the GOA circuit module and a gate electrode of the third TFT; and a source electrode of the third TFT is electrically connected with a drain electrode of the fourth TFT; and
a gate electrode of the first TFT, a drain electrode of the first TFT, and a drain electrode of the third TFT are electrically connected with a first voltage source (VGH); and a source electrode of the second TFT and a source electrode of the fourth TFT are electrically connected with a second voltage source (VSS).

8. The liquid crystal display panel according to claim 7, wherein the amplification circuit module further comprises a first capacitor, the first capacitor being connected between the gate electrode and the source electrode of the third TFT.

9. The liquid crystal display panel according to claim 6, wherein the GOA circuit module comprises a pull-down holding circuit unit, a second capacitor, a fifth TFT, and a sixth TFT, the pull-down holding circuit unit comprising a first terminal, a second terminal, a third terminal, and a fourth terminal;
a source electrode of the fifth TFT is electrically connected with the first terminal and a gate electrode of the sixth TFT, a source electrode of the sixth TFT being electrically connected with the third terminal, the first output terminal, and the second voltage source (VSS), a gate electrode and a drain electrode of the fifth TFT being electrically connected with the first input terminal; a drain electrode of the sixth TFT and the fourth terminal are electrically connected with the second input terminal, the second terminal being electrically connected with the second voltage source (VSS); and the second capacitor is connected between the gate electrode and the source electrode of the sixth TFT.

10. The liquid crystal display panel according to claim 9, wherein the GOA circuit module further comprises: a seventh TFT and an eighth TFT;
a drain electrode of the seventh TFT is electrically connected with the source electrode of the fifth TFT and the gate electrode of the sixth TFT, a gate electrode of the seventh TFT being electrically connected with a gate electrode of the eighth TFT, a drain electrode of the eighth TFT being electrically connected with the source electrode of the sixth TFT; and a source electrode of the seventh TFT and a drain electrode of the eighth TFT are electrically connected with the second voltage source (VSS).
